(19) United States
(12) Patent Application Publication
(10) Pub. No.: US 2020/0290150 A1
(43) Pub. Date: Sep. 17, 2020

(54) JOINED COMPONENT AND METHOD OF MANUFACTURING SAME

(71) Applicant: POINT ENGINEERING CO., LTD., Asan (KR)

(72) Inventor: Bum Mo AHN, Suwon (KR)

(21) Appl. No.: 16/814,865

(22) Filed: Mar. 10, 2020

(30) Foreign Application Priority Data
Mar. 13, 2019 (KR) 10-2019-0028908

(51) Int. Cl. B23K 20/12; C23C 16/455; H01L 21/67

(52) U.S. Cl. CPC B23K 20/12; H01L 21/67011; C23C 16/45565

(57) ABSTRACT

The present invention relates to a joined component formed by friction stir welding and, more particularly, to a joined component formed in a structure in which no interface exists between flow paths formed therein.

### CROSS REFERENCE TO RELATED APPLICATION

The present application claims priority to Korean Patent Application No. 10-2019-0028908, filed Mar. 13, 2019, the entire contents of which is incorporated herein for all purposes by this reference.

### BACKGROUND OF THE INVENTION

### Field of the Invention

The present invention relates to a joined component that is formed by friction stir welding.

### Description of the Related Art

As a technique for depositing a thin film on a semiconductor substrate or glass, chemical vapor deposition (CVD) or atomic layer deposition (ALD), which are thin-film deposition techniques based on a chemical reaction, is used.

Equipment for performing thin-film deposition, such as CVD or ALD, is used to manufacture semiconductor devices. Such thin-film deposition equipment usually includes a showerhead provided inside a chamber to supply a reaction process fluid required for depositing a thin film on a wafer. The showerhead serves to spray the reaction process fluid onto the wafer in the proper distribution range required for thin film deposition.

One example of the showerhead is disclosed in Korean Patent No. 10-0769522 (hereinafter, referred to as “Patent Document 1”).

In Patent document 1, a showerhead is configured to spray a reaction gas introduced into a main hole and an auxiliary hole onto the wafer surface through a guide groove.

On the other hand, inside a vacuum chamber used for display manufacturing, a diffuser may be provided to uniformly spray gas onto glass. A display is a non-light emitting device in which liquid crystals are injected between an array substrate and a color filter substrate to obtain an image effect by using the characteristics thereof. The array substrate and the color filter substrate may be manufactured in such a manner that a thin film is repeatedly deposited onto a transparent substrate made of glass or the like, and patterning and etching are followed. In this case, when a reaction material and a source material in a gaseous phase are introduced into the vacuum chamber in a deposition process, introduced gases are passed through the diffuser and deposited onto glass installed on a susceptor to form a film.

One example of the diffuser is disclosed in Korean Patent No. 10-1352923 (hereinafter, referred to as “Patent Document 2”).

In Patent Document 2, a diffuser is disposed in an upper region in the chamber to provide a deposition material onto the surface of a glass substrate.

Fluid passing members such as the showerhead of Patent Document 1 and the diffuser of Patent Document 2 may be influenced by the temperature inside an enclosed process chamber. When a fluid passing member is under influence by temperature, a temperature deviation may occur in the fluid passing member itself, which may cause deformation to occur. This may cause a problem in that the direction and density of process fluid distribution may not be uniform. In other words, when the fluid passing member is influenced by the temperature inside the process chamber, there may arise a problem in that deformation of a product may occur, which may adversely influence functions of the product.

On the other hand, in order to compensate for the adverse influence of temperature on the fluid passing member, as illustrated in FIGS. 1A and 1B, it may be considered to provide a fluid passing member, which includes a space therein capable of controlling the temperature of the fluid passing member. As a method of manufacturing a fluid passing member having a space capable of controlling temperature therein, a method of welding or brazing a metal filler material in a molten state may be used. FIGS. 1A and 1B are views illustrating a technology underlying the present invention, in which a portion of a fluid passing member manufactured by welding or brazing a metal filler material in a molten state is illustrated enlarged. FIG. 1A is a view illustrating parent members 1 in a state before the method of welding or brazing the metal filler material in a molten state is used. FIG. 1B is a view illustrating a portion of a fluid passing member manufactured by the method of welding or brazing the metal filler material in the molten state.

As illustrated in FIG. 1A, grooves 2 may be formed in opposed contact surfaces of the respective parent members 1 in an opposed relationship to form temperature control spaces. The parent members 1 in which the grooves 2 are formed may be welded or brazed by using the molten metal filler material. After welding or brazing, holes 4 may be formed by use of a perforation method in regions in which no temperature control space is formed.

However, due to the fact the above technology uses a method of welding or brazing a metal filler material (e.g., filler metal in the case of welding) in a molten state, there may arise a problem that when the process fluid is injected through the holes 4, the metal filler material of weld joints or braze joints 3 formed between the parent members 1, may be exposed to the process fluid, thus leading to increased corrosion. In detail, the above technology is characterized in that the weld joints or braze joints 3 also exist at inner surfaces of the holes 4. Due to this, there may arise a problem in that the weld joints or braze joints 3 may be exposed due to the process fluid injected through the inner surfaces of the holes 4, causing corrosion.

Such problems may be transferred to temperature control spaces such as the grooves 2 through the weld joints or braze joints 3, which are interfaces between the parent members 1, to adversely influence the temperature control spaces. This may result in occurrence of serious functional errors of the temperature control spaces. When a functional error of the temperature control spaces occurs, there may arise a problem in that temperature distribution of a fluid passing member may become uneven, which may cause positional deformation of the holes 4 and further cause deformation of a product itself. This may cause a problem of a functional error of the fluid passing member to occur.

Furthermore, in the fluid passing member such as the showerhead of Patent Document 1 and the diffuser of Patent Document 2, fluid holes formed in communication with the grooves 2 and through which a process fluid different from the process fluid passing through the holes 4 passes may be provided. Consequently, a structure for spraying different process fluids may be formed.

However, the fluid passing member of the above technology formed by the method of welding or brazing the metal filler material are problematic in that in the structure of spraying different process fluids, the metal filler material of the weld joints or braze joints 3 may be exposed to the process fluid and corrosion may be increased.

This may cause a problem that when the process fluids are sprayed from the fluid passing member, particles which may be generated due to corrosion may be sprayed theretogether. This not only adversely affects formation of a film on a wafer or glass but may also result in production of defective products.

As such, according to the technology underlying the present invention, a conventional welding method has disadvantages that may cause various problems.

The foregoing is intended merely to aid in the understanding of the background of the present invention, and is not intended to mean that the present invention falls within the purview of the related art that is already known to those skilled in the art.

### Documents of Related Art

(Patent document 1) Korean Patent No. 10-0769522

(Patent document 2) Korean Patent No. 10-1352923

### SUMMARY OF THE INVENTION

Accordingly, the present invention has been made keeping in mind the above problems occurring in the related art, and an objective of the present invention is to provide a joined component that is manufactured by friction stir welding in a structure in which flow paths are not in communication with each other, and no interface exists between the flow paths, thereby preventing an adverse action from occurring due to the interface.

In order to achieve the above objective, according to one aspect of the present invention, there is provided a joined component formed by welding at least two parent members by friction stir welding, the joined component including: a hollow channel formed inside the joined component and in which a temperature control means is provided; a communication line formed inside the joined component and being in communication with the hollow channel; and a fluid hole vertically passing through the parent members in a weld zone formed by friction stir welding, and through which a process fluid passes, wherein the weld zone formed by friction stir welding that is formed between the hollow channel and the fluid hole removes at least a part of a horizontal interface between the hollow channel and the fluid hole.

Furthermore, the temperature control means may be a fluid or a heating wire.

Furthermore, opposite ends of the hollow channel may be in communication with the communication line.

Furthermore, the communication line may be formed peripherally outside the hollow channel while forming a closed curve.

Furthermore, the fluid hole may be formed between neighboring hollow channels.

Furthermore, a weld zone formed by friction stir welding may be formed outside the communication line.

Furthermore, a direction in which the hollow channel is formed and a direction in which the fluid hole is formed may be perpendicular to each other.

Furthermore, an inner surface of each of the hollow channel, the communication line, and the fluid hole, and a surface of the joined component may be anodized or plated.

According to another aspect of the present invention, there is provided a joined component formed by welding at least two parent members by friction stir welding, the joined component including: a first fluid hole vertically passing through the parent members in a weld zone formed by friction stir welding, and through which a first process fluid passes; a second fluid hole being in communication with a hollow channel formed inside the joined component, and through which a second process fluid passes; and a communication line formed inside the joined component to be in communication with the hollow channel, and being in communication with an injection port through which the second process fluid is injected into the hollow channel, wherein the weld zone formed by friction stir welding that is formed between the first and second fluid holes removes at least a part of a horizontal interface between the first and second fluid holes, and the first process fluid is introduced into the first fluid hole and the second process fluid is introduced into the second fluid hole, such that the first and second fluid holes respectively supply different process fluids separately.

Furthermore, an inner surface of each of the first fluid hole, the second fluid hole, and the communication line, and a surface of the joined component may be anodized or plated.

Furthermore, the joined component may be a joined component provided in etching equipment, cleaning equipment, heat treatment equipment, ion implantation equipment, sputtering equipment, or CVD equipment, and through which a process fluid for a semiconductor manufacturing process or display manufacturing process passes.

According to still another aspect of the present invention, there is provided a method of manufacturing a joined component, the method including: welding at least two parent members each of which includes at least one groove by a first friction stir welding, thereby forming a joined component such that a hollow channel is formed in the joined component by the groove; welding an upper surface of the joined component by a second friction stir welding to close at least one end of the hollow channel and form an outer peripheral region, and performing grooving in a region inside the outer peripheral region along the outer peripheral region, thereby forming a communication line; and forming a first fluid hole vertically passing through the parent members in a weld zone formed by the first friction stir welding, and through which a first process fluid passes.

The method may further include: forming a second fluid hole being in communication with the hollow channel, and through which a second process fluid passing through a lower portion of the joined component passes.

As described above, the joined component according to the present invention is formed in a structure in which flow paths provided therein are not in communication with each other by weld zones. Furthermore, a structure in which no horizontal interface exists by the weld zones formed between the respective flow paths is formed, and thus it is possible to prevent adverse interaction that may occur between the paths due to horizontal interfaces.

Furthermore, each of the flow paths has no horizontal interface existing at the inner surface thereof, thereby making it possible to prevent the problem of increased corrosion, and particle generation, which may occur due to existence of the horizontal interface at the inner surface. Consequently, it is possible to reduce the rate of defective products that may occur due to spraying of process fluids in which particles are entrained.

### BRIEF DESCRIPTION OF THE DRAWINGS

The above and other objectives, features, and other advantages of the present invention will be more clearly understood from the following detailed description when taken in conjunction with the accompanying drawings, in which:

FIGS. 1A to 1B are views schematically illustrating a technology underlying the present invention;

FIGS. 2A and 2B are views schematically illustrating a joined component according to an exemplary embodiment of the present invention;

FIGS. 3A to 5E are views schematically illustrating a manufacturing process of the joined component of the embodiment of the present invention;

FIG. 6 is a partially sectioned perspective view illustrating the joined component of the embodiment;

FIG. 7 is a view illustrating a modification of the embodiment of the present invention; and

FIGS. 8A and 8B are views schematically illustrating semiconductor or display manufacturing process equipment including the joined components of the embodiment and the modification of the present invention.

### DETAILED DESCRIPTION OF THE INVENTION

The following description merely exemplifies the principle of the present invention. Thus, although not explicitly described or shown in this disclosure, various devices in which the principle of the present invention is implemented and which are encompassed in the concept or scope of the present invention can be invented by one of ordinary skill in the art. It should be appreciated that all the conditional terms enumerated herein and embodiments are clearly intended only for a better understanding of the concept of the present invention, and the present invention is not limited to the particularly described embodiments and statuses.

The forgoing objectives, advantages, and features of invention will become more readily apparent from the following detailed description taken in conjunction with the accompanying drawings, and accordingly, one of ordinary skill in the art may easily practice the embodiment of the present invention.

Embodiments are described herein with reference to sectional and/or perspective illustrations that are schematic illustrations of idealized embodiments. Also, for convenience of understanding of the elements, in the figures, thicknesses of members and regions and diameters of holes may be exaggerated to be large for clarity of illustration. As such, variations from the shapes of the illustrations as a result, for example, of manufacturing techniques and/or tolerances, are to be expected. In addition, the number of holes shown in the drawings is by way of example only. Thus, embodiments should not be construed as limited to the particular shapes illustrated herein but are to include deviations in shapes that result, for example, from manufacturing.

Wherever possible, the same reference numerals will be used throughout different embodiments and the description to refer to the same or like elements or parts having like functions throughout. Furthermore, the configuration and operation already described in other embodiments will be omitted for convenience of the description.

A joined component according to the present invention may have a structure formed by welding at least two parent members by friction stir welding and in which no interface exists between flow paths (e.g., fluid paths such as hollow channels, first and second fluid holes, and the like) formed in the joined component. In the case of the joined component, the structure thereof is not limited as long as a structure formed by friction stir welding and in which no interface exists between the flow paths (e.g., fluid paths such as hollow channels, first and second fluid holes, and the like).

The joined component may be a showerhead or diffuser capable of spraying a process fluid onto a wafer or glass in a semiconductor or display process.

The joined component may include a temperature control means in a hollow channel when focusing on the aspect of temperature control, and may include first and second fluid holes when focusing on the aspect of spraying different process fluids. In this case, due the structure of the joined component in which not interface exists between the flow paths (e.g., fluid paths such as hollow channels, first and second fluid holes, and the like), it is possible to prevent an adverse action from occurring in the hollow channels or the first and second fluid holes along interfaces.

Hereinafter, the joined component formed by friction stir welding will be exemplarily described as the diffuser capable of spraying the process fluid in the semiconductor or display manufacturing process.

Hereinafter, exemplary embodiments of the present invention will be described in detail with reference to the accompanying drawings.

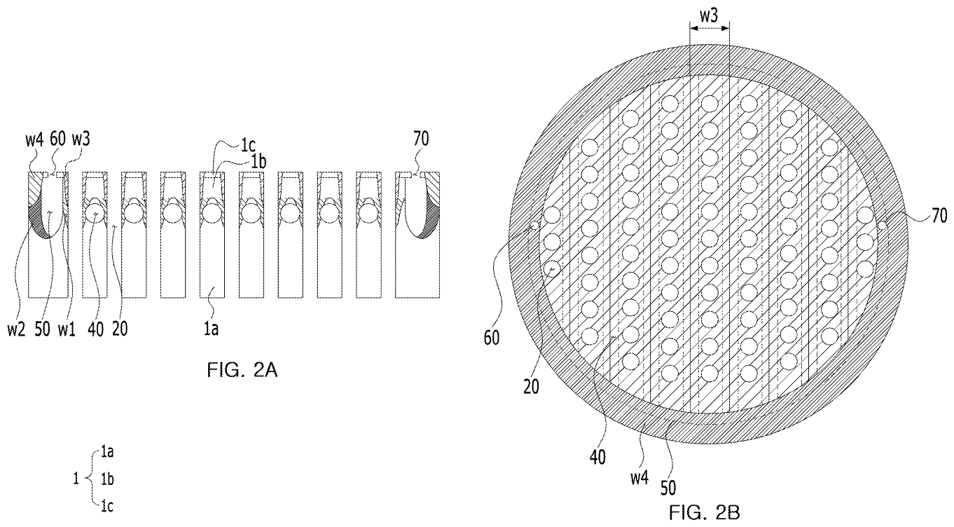

FIGS. 2A and 2B are views schematically illustrating a joined component, formed by friction stir welding which is a technical feature of the present invention. FIG. 2A is a view illustrating a section of a joined component 100, and FIG. 2B is a view illustrating the joined component 100 when viewed from above.

As illustrated in FIG. 2A, the joined component 100 may include at least two parent members 1, a hollow channel 40 formed inside the joined component 100 and in which a temperature control means is provided, a communication line 50 provided inside the joined component 100, and a fluid hole 20 vertically passing through the parent members 1.

The joined component 100 according to the present invention may be formed in such a manner that first and second parent members 1a and 1b in which grooves are formed are welded by friction stir welding, and a third parent member 1c is welded onto the first and second parent members 1a and 1b by friction stir welding. Although three parent members 1 are stacked on top of each other and welded by friction stir welding, this is only an example. Therefore, the number of the parent members 1 is not limited thereto.

As illustrated in FIG. 2A, the parent members 1 may be stacked on top of each other and welded by friction stir welding. In the drawing of FIG. 2A, an uppermost parent member stacked on the uppermost side in FIG. 2A among the parent members 1 may be the third parent member 1c, and parent members located below the third parent member 1c may be first and second parent members 1a and 1b welded by friction stir welding. As one example, the parent members 1 may be stacked in such a manner that the first parent member 1a, the second parent member 1b, and the third parent member 1c are sequentially stacked from bottom to top.

A weld zone may be formed at the joined component 100 Consequently of welding the parent members 1 by friction stir welding.

Friction stir welding is a process that joins workpieces without melting the workpiece material. Friction stir welding can reduce generation of defects such as pores, solidification cracks, and residual stresses due to a phase change from liquid to solid, which is advantageous over conventional welding or brazing. When friction stir welding is performed along a contact junction formed at each interface between the parent members 1, a pin 10b is brought into friction contact with the parent members and generates heat. In this state, a shoulder 10a coupled to an upper portion of the pin 10b is brought into contact with the parent members and expands the heating area. Then, the pin 10b or the parent members 1 are moved to cause the material under the pin to plastically flow to form a friction stir welding nugget zone. The nugget zone is a region where recovery and recrystallization occurs due to high heat and the amount of deformation, also called a dynamic recrystallization zone.

Unlike general welding in which melting occurs due to heat, the nugget zone is formed through dynamic recrystallization of the material which occurs in a solid state below the melting point due to frictional heat and stirring. The diameter of the nugget zone is larger than that of the pin 10b while being smaller than that of the shoulder 10a. The size of the nugget zone depends on the speed of rotation of a welding tool 10 including the pin 10b and the shoulder 10a. As the speed of rotation increases, the size of the nugget zone decreases. However, when the speed of rotation is too high, the shape of crystal grains may be incomplete, and defects may occur at the incomplete portion. In the vicinity of the nugget zone where the parent members 1 are mixed during friction stir welding, a thermo-mechanically affected zone (TMAZ) surrounding the nugget zone is formed, and a heat affected zone (HAZ) surrounding the thermo-mechanically affected zone is formed.

The thermo-mechanically affected zone is a region where partial recrystallization occurs due to plastic deformation caused by friction at a contact surface where the shoulder 10a of the welding tool 10 is brought into contact with the parent members, and where thermal deformation due to friction and mechanical deformation due to the shoulder 10a simultaneously occur. In the thermo-mechanically affected zone, crystals softened due to excessive plastic flow and deformation of the material may be distributed at an angle.

The heat affected zone is a region more affected by heat than the thermo-mechanically affected zone, in which slant crystal grains are present and many pores are present.

The weld zone formed by friction stir welding may be a region including the nugget zone, the thermo-mechanically affected zone, and the heat affected zone. Preferably, the weld zone may be a region where the nugget zone and the thermo-mechanically affected zone are formed below each interface between the parent members 1, or a region where the nugget zone is formed below each interface between the parent members 1.

The material of the parent members 1 may be any material enabling that: i) frictional heat is generated by friction between the pin 10b rotating at a high speed and the parent members 1, ii) the parent members 1 around the pin 10b are softened by the frictional heat, and iii) the parent members 1 are forcibly mixed together by plastic flow of the parent members 1 occurring on the joined surfaces by a stirring action of the pin 10b. The material of the parent members 1 constituting the joined component 100 may be made of at least one of aluminum, aluminum alloy, titanium, titanium alloy, magnesium, magnesium alloy, carbon steel, and stainless steel. The material of the parent members 1 may be made of at least one of non-ferrous metal including aluminum, aluminum alloys, titanium, titanium alloys, magnesium, magnesium alloys, and the like, and carbon steel, and stainless steel, but is not limited thereto.

When the at least two parent members 1 are welded by friction stir welding, the at least two parent members 1 may be made of different metal materials. For example, when the first parent member 1a is made of aluminum, which is one of the above materials, the second parent member 1b may be made of stainless steel. On the other hand, the parent members 1 may be made of the same metal material. For example, when the first parent member 1a is made of aluminum, the second parent member 1b may also be made of aluminum, and when the first parent member 1a is made of stainless steel, the second parent member 1b may also be made of stainless steel. Friction stir welding is a solid-state joining process, and thus members having different melting points can be stably joined. In other words, it is possible to stably join different metal materials. In particular, the nugget zone included in the weld zone is a region in which dynamic recrystallization occurs, and thus the nugget zone has a structure resistant to external vibrations and impacts. Furthermore, the thermo-mechanically affected zone included in the weld zone is a region in which the parent members 1 are mixed and joined, and thus thermo-mechanically affected zone has a structure resistant to external vibrations and impacts. Unlike other welding processes such as a welding process of joining a metal filler material in a molten state, a brazing process, and the like, friction stir welding does not require a heat source, a welding rod, a filler metal, and the like, and thus no harmful rays or harmful substances are emitted during welding. Furthermore, dynamic recombination occurs and thus it is possible to prevent solidification cracks which may occur in conventional welding, and there is little deformation and thus mechanical properties are excellent.

According to the present invention, it is ensured that a weld zone having such a high strength and weldability removes at least a part of a horizontal interface between the hollow channel 40 formed inside the joined component 100 and in which the temperature control means is provided, and the fluid hole 20 through which a process fluid passes. This therefore prevents particles generated inside the fluid hole 20 from moving to the hollow channel 40. It is further ensured that the process fluid passing through the fluid hole 20 is prevented from penetrating along the horizontal interface to reach the hollow channel 40, and the temperature control means such as a temperature control fluid passing through the hollow channel 40 is prevented from penetrating along the horizontal interface to reach the fluid hole 20.

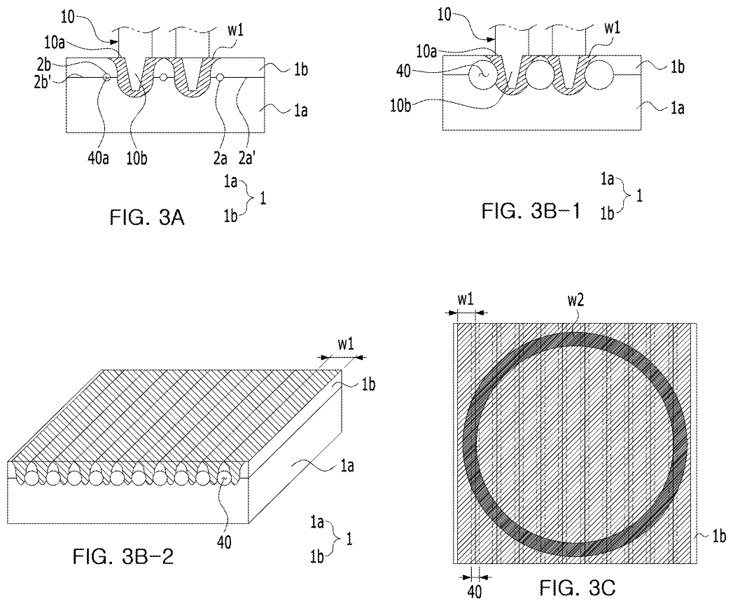

As illustrated in FIG. 2A, the hollow channel 40 is formed inside the joined component 100. When the first and second parent members 1a and 1b in which the grooves are formed are welded by friction stir welding, the grooves formed in the respective parent members are located opposed to each other, and the hollow channel 40 is formed by the opposed grooves. In this case, before the hollow channel 40 is formed by the opposed grooves, a hollow 40a may be first formed, and the hollow 40a may be enlarged by boring to form the hollow channel 40. A detailed description thereof will be described later in a method of manufacturing the joined component 100 with reference to FIGS. 3A to 5E.

A groove may be formed in at least one of opposed contact surfaces of the parent members 1. In the present invention, it will be described that the groove is formed in each of the opposed contact surfaces of the first and second parent members 1a and 1b such that the respective grooves are located at positions corresponding to each other to form the hollow 40a having a circular cross-section inside the joined component 100, and boring is performed on the hollow 40a to form the hollow channel 40. In FIG. 2, a structure in which the hollow channel 40 is formed is illustrated.

The groove is formed on at least one of the opposed contact surfaces of the parent members 1 and provides a space in which a fluid moves or a separate member is provided when the parent members 1 are welded by friction stir welding and formed into the joined component 100 for the semiconductor or display manufacturing process.

The first parent member 1a includes a first groove region in which a first groove 2a is formed and a first non-groove region 2a′ in which the first groove 2a is not formed.

The second parent member 1b includes a second groove region in which a second groove 2b is formed and a second non-groove region 2b′ in which the second groove 2b is not formed.

In this case, the first groove region of the first parent member 1a and the second groove region of the second parent member 1b, which are in an opposed relationship, may not be welded, while the first non-groove region 2a′ and the second non-groove region 2b′, which are in an opposed relationship, may be welded by friction stir welding to form a weld zone. The friction stir welding performed on the first non-groove region 2a′ and the second non-groove region 2b′ is a first friction stir welding performed on the joined component 100, and a weld zone formed by the first friction stir welding may be a first weld zone w1.

The first groove region and the second groove region which are not welded together may be surrounded by the first weld zone w1. Since the hollow channel 40 is formed by enlarging the opposed first groove 2a and the second groove 2b opposed to each other by boring, at least a part of the first weld zone w1 may be removed by boring. Due thereto, an inner surface of the hollow channel 40 may be formed in a state where no horizontal interface exists due to the first weld zone w1.

A groove having a semicircular cross-section may be formed in each of the first and second parent members 1a and 1b, and boring may be performed on the respective grooves to form the hollow channel 40 having a circular cross-section. However, this is illustrated only as one example, and thus the shape of the grooves and the hollow channel 40 is not limited thereto.

The hollow channel 40 may include the temperature control means. By the provision of the temperature control means in the hollow channel 40, the joined component 100 can perform a temperature control function of controlling the temperature of the joined component 100 itself.

The temperature control means provided in the hollow channel 40 may be a fluid or a heating wire.

When the temperature control means is the fluid, a cooling fluid or a heating fluid may be provided. When the temperature control means is the cooling fluid, the joined component 100 may function as a cooling block. On the other hand, when the temperature control means is the heating fluid, the joined component 100 may function as a heating block.

When the temperature control means is the fluid, the inner surface of the hollow channel 40 may be anodized or plated. This can prevent corrosion of the inner surface of the hollow channel 40 due to the fluid.

When the temperature control means is a heating wire, the joined component 100 may function as a heater.

The provision of the temperature control means in the hollow channel 40 as described above ensures that the joined component 100 secures temperature uniformity. Consequently, it is possible to obtain an effect of minimizing the problem of malfunction due to deformation of a product.

At least a part of the first weld zone w1 may exist around the hollow channel 40 in which the temperature control means is provided. Since the hollow channel 40 is formed by enlarging the first groove 2a and the second groove 2b, which are opposed to each other when the first and second parent members 1a and 1b are welded by friction stir welding, by boring, the hollow channel 40 may be formed while removing a part of the first weld zone w1. Therefore, the hollow channel 40 may be formed in a form in which at least a part of the first weld zone w1 exists around the hollow channel 40, and no horizontal interface exists at the inner surface thereof by the first weld zone w1.

Due to such a structure, the hollow channel 40 in which the temperature control means is provided can be prevented from being adversely influenced by particles generated due to corrosion of the horizontal interface.

A plurality of grooves may be formed in each of the first and second parent members 1a and 1b, and thus a plurality of hollow channels 40 may be formed in the joined component 100. These hollow channels 40 may be in communication with each other by the communication line 50 in communication with opposite ends of each of the hollow channels 40.

As illustrated in FIG. 2B, the communication line 50 is formed peripherally outside the hollow channels 40 while forming a closed curve. A closed curve indicated by a dotted line illustrated in FIG. 2B represents the communication line 50.

The respective opposite ends of the hollow channels 40 are in communication with the communication line 50. Due to the communication line 50 in communication with the opposite ends of the hollow channels 40, the hollow channels 40 are in communication with each other. Due to such a structure, when the fluid is provided as the temperature control means, the fluid can be uniformly moved inside the joined component 100 along the hollow channels 40 and the communication line 50 inside the joined component 100, thereby making it possible to secure uniformity of the temperature of the joined component 100.

When the temperature control means provided in each of the hollow channels 40 is the fluid, ab inner surface of the communication line 50 may be anodized or plated. This can prevent the problem that the communication line 50 may be corroded by the fluid flowing inside the communication line 50.

When the temperature control means provided in the hollow channels 40 is the fluid, an injection port 60 through which the fluid is injected into the joined component 100 and a discharge port 70 through which the fluid is discharged from the joined component 100 may be formed in communication with the communication line 50. The injection port 60 and the discharge port 70 may be formed to vertically pass through the third parent member 1c and to be in communication with the communication line 50.

On the other hand, when the temperature control means provided in each of the hollow channels 40 is the heating wire, the injection port 60 and the discharge port 70 may function as an injection port and a discharge port through which the heating wire is introduced into and withdrawn from the joined component 100.

The injection port 60 and the discharge port 70 may be respectively formed at one end and the other end of the third parent member 1c to vertically pass through the third parent member 1c and to be in communication with the communication line 50. However, the position where the injection port 60 and the discharge port 70 are provided is not limited thereto. For example, the injection port 60 and the discharge port 70 may be formed to be in communication with the communication line 50 at positions opposite to each other with the hollow channels 40 interposed therebetween.

In the present invention, although the injection port 60 and the discharge port 70 are in communication with the communication line 50 while vertically passing through the third parent member 1c, as one example, the injection port 60 and the discharge port 70 may be formed at an outside of an outer peripheral region existing outside the communication line 50 as illustrated in FIG. 2A so as to be in communication with the communication line 50 while passing through the outer peripheral region. In this case, at least one of the injection port 60 and the discharge port 70 may be formed to be in communication with the communication line 50 while passing through the left side (in FIG. 2A) of the outer peripheral region existing outside the communication line 50, and at least one of the injection port 60 and the discharge port 70 may be formed to be in communication with the communication line 50 while passing through the right side (in FIG. 2A) of the peripheral region existing outside the communication line 50.

Furthermore, as one example, the injection port 60 and the discharge port 70 may be formed to be in communication with the communication line 50 while at least partially passing through the joined component 100 from a lower surface (in FIG. 2A) of the joined component 100 to the communication line 50. Such a structure may be a structure formed to be in communication with the communication line 50 while at least partially passing through the joined component 100 at a location opposite to the injection port 60 and the discharge port 70 illustrated in FIG. 2A.

In the present invention, as one example, the lift side in FIG. 2B may be one end of the third parent member 1c and the right side in FIG. 2B may be the other end of the third parent member 1c. Furthermore, as one example, a configuration formed at one end of the third parent member 1c may be the injection port 60 and a configuration formed at the other end of the third parent member 1c may be the discharge port 70. One end and the other end of the third parent member 1c are not limited thereto, and the positions of the injection port 60 and the discharge port 70 formed at one end and the other end of the third parent member 1c are not limited thereto.

The communication line 50 may be formed in such a manner that friction stir welding is performed on an upper surface of the joined component 100 in which the first and second parent members 1a and 1b are joined to form a weld zone, and grooving is performed in a region inside the weld zone. Therefore, the communication line 50 may be provided in a form in which a weld zone formed by friction stir welding is formed outside the communication line 50. In this case, the friction stir welding performed on the upper surface of the joined component 100 in which the first and second parent members 1a and 1b are joined may be a second friction stir welding, a weld zone formed thereby may be a second weld zone w2. A detailed description thereof will be described later in a method of manufacturing the joined component 100 with reference to FIGS. 3A to 5E.

Referring to FIG. 2A again, the third parent member 1c is stacked on the first and second parent members 1a and 1b and welded thereto by friction stir welding to form a weld zone. The friction stir welding performed on the third parent member 1c stacked on the first and second parent members 1a and 1b may be a third friction stir welding, a weld zone formed thereby may be a third weld zone w3. The third weld zone w3 may be formed by welding one region of the third parent member 1c opposite to the first weld zone w1 by the third friction stir welding. Consequently, the first and third weld zones w1 and w3 may be formed at positions corresponding to each other.

The third weld zone w3 is a weld zone which is formed to remove at least a part of each horizontal interface of the joined component 100 formed by welding the third parent member 1c and the first and second parent members 1a and 1b by first friction stir welding. Therefore, the third weld zone w3 may be formed in the other region of the third parent member 1c which is opposed to a non-weld region where no first weld zone w1 is formed. In other words, the position where the third weld zone w3 is formed is not limited to the position corresponding to the first weld zone w1.

In the present invention, as one example, the first weld zone w1 will be described as being formed at a position corresponding to the first weld zone w1 by welding one region of the third parent member 1c opposed to the first weld zone w1 by friction stir welding.

The fluid hole 20 passing through the first weld zone w1 and the third weld zone w3 is formed at a position where the first weld zone w1 and the third weld zone w3 are formed. In other words, the fluid hole 20 which vertically passes through the parent members 1 is formed in weld zones such as the first and third weld zones w1 and w3 formed by friction stir welding. The fluid hole 20 provides a passage through which a process fluid passes.

When the third weld zone w3 is formed in the other region of the third parent member 1c opposite to the non-weld region where no first weld zone w1 is formed, that is, when the third weld zone w3 is formed at a position that does not correspond to the first weld zone w1, the fluid hole 20 may be formed through the first weld zone w1.

As illustrated in FIG. 2A, the fluid hole 20 passes through the first and third weld zones w1 and w3 while vertically passing through the parent members 1. Since the fluid hole 20 passes through the first and third weld zones w1 and w3 while vertically passing through the parent members 1, the fluid hole 20 may be formed in a form in which no horizontal interface exists at an inner surface thereof.

When the third weld zone w3 is formed at a position that does not correspond to the first weld zone w1, since the third weld zone w3 is formed in the other region of the third parent member 1c opposite to the non-weld region, no horizontal interface may exist at the inner surface of the fluid hole 20.

Since no horizontal interface exists at the inner surface of the fluid hole 20 due to the weld zone, problems such as introduction of foreign substances introduced along the horizontal interface and corrosion of the horizontal interface may not occur.

The inner surface of the fluid hole 20 may be anodized or plated. This can prevent corrosion of the inner surface of the fluid hole 20 due to the process fluid passing through the fluid hole 20.

The fluid hole 20 formed through the parent members 1 in the first and third weld zones w1 and w3 may be located between each neighboring hollow channels 40. The fluid hole 20 and each of the hollow channels 40 may be configured such that at least a part of the first weld zone w1 and at least a part of the third weld zone w3 are formed between the fluid hole 20 and the hollow channel 40. This can prevent adverse interaction which may occur between the fluid hole 20 and the hollow channel 40. The adverse interaction here may denote that the process fluid passing through the fluid hole 20 affects the hollow channel 40 along a horizontal interface, or that the fluid is introduced into the fluid hole 20 along the horizontal interface when the temperature control means provided in the hollow channel 40 is the fluid.

As illustrated in FIG. 2A, weld zones formed between the fluid hole 20 and the hollow channel 40 may remove at least a part of a horizontal interface between the fluid hole 20 and the hollow channel 40. In detail, as illustrated in FIG. 2A, when the fluid hole 20 is formed through the parent members 1 in the first and third weld zones w1 and w3, the first and third weld zones w1 and w3 may remove at least a part of the horizontal interface between the fluid hole 20 and the hollow channel 40.

On the other hand, when the third weld zone w3 is formed in the other region of the third parent member 1c opposite to the non-weld region, which is a position not corresponding to the first weld zone w1, a weld zone formed between the fluid hole 20 and the hollow channel 40 is the first weld zone w1 and may remove at least a part of the horizontal interface between the fluid hole 20 and the hollow channel 40.

This can prevent adverse interaction that may occur between the fluid hole 20 and the hollow channel 40 along each horizontal interface of the parent members 1.

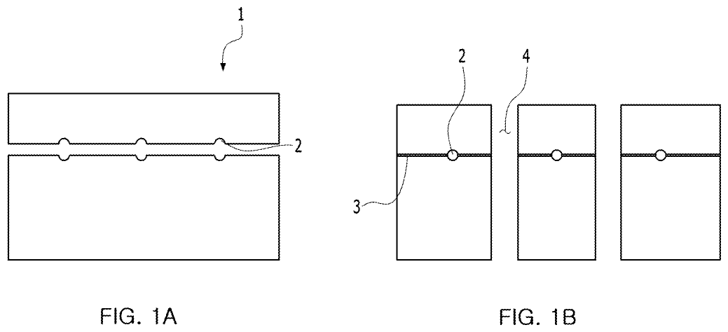

When the parent members 1 are joined by welding or brazing as the technology underlying the present invention, as illustrated in FIG. 1B, weld joints or braze joints 3 are formed at junctions between the first and second parent members 1a 1b. In this case, the weld joints or braze joints 3 may be exposed to the process fluid injected into holes 4.

However, the joined component 100 according to the present invention may have a structure in which no horizontal interface exists by forming weld zones by friction stir welding. By forming the fluid hole 20 and the hollow channel 40 in this structure, it is possible to provide a structure in which no horizontal interface exists between the fluid hole 20 and the hollow channel 40. Consequently, the fluid hole 20 and the hollow channel 40 may be formed to be isolated from each other inside the joined component 100 without being in communication with each other. This can reduce the risk of increased corrosion and particle generation at the horizontal interface.

In the joined component 100 according to the present invention, no horizontal interface exists in the hollow channel 40 formed by enlarging the first and second grooves while removing a part of the first weld zone w1, and the fluid hole 20 formed through the parent members 1 in the first weld zone w1 and the third weld zone w3. This can prevent problems such as corrosion and leakage at the horizontal interface, and it is possible to obtain an effect of reducing a defect rate of a product.

The surface of the joined component 100 may be anodized or plated. Therefore, when the joined component 100 is used in the semiconductor or display manufacturing process, corrosion during the process can be prevented and thus corrosion resistance can be improved.

Hereinafter, a method of manufacturing a joined component 100 according to the present invention will be described with reference to FIGS. 3A to 5E.

The method of manufacturing the joined component 100 according to the present invention includes forming a joined component 100 such that a hollow channel 40 is formed therein, forming a communication line 50, and forming a first fluid hole 20.

FIGS. 3A, 3B-1, and 3B-2 illustrate the forming the joined component 100 such that the hollow channel 40 is formed therein.

First, as illustrated in FIG. 3A, a process of welding by a first friction stir welding at least two parent members 1 in which grooves are formed on at least one of opposed contact surfaces thereof is performed.

In this case, the at least two parent members 1 in which the grooves are formed may be comprised of first and second parent members 1a and 1b. A parent member located on the lower side in FIG. 3A may be the first parent member 1a, and a parent member stacked on the first parent member 1a may be the second parent member 1b.

The grooves may be comprised of first grooves 2a formed in the first parent member 1a and second grooves 2b formed in the second parent member 1b and may be formed in the respective parent members 1.

The first parent member 1a in which the first grooves 2a are formed and the second parent member 1b in which the second grooves 2b are formed are located such that the first and second grooves 2a and 2b are opposed to each other, and first non-groove regions and second non-groove regions opposed to each other are welded by the first friction stir welding.

The first friction stir welding may be performed along at a least a part of each of horizontal interfaces between the parent members 1 to weld each of the first non-groove regions and each of the second non-groove regions opposed to each other. The at least a part of each of the horizontal interfaces between the parent members 1 is a contact junction, and the first friction stir welding may be performed along the respective contact junctions. The parent members 1 are joined by the first friction stir welding to form weld zones. The weld zones formed by the first friction stir welding may be first weld zones w1.

As illustrated in FIG. 3A, the first and second parent members 1a and 1b are welded by friction stir welding to form the first weld zones w1, and a hollow 40a having a circular cross-section may be formed by each of the first grooves 2a and each of the second grooves 2b.

Then, as illustrated in FIG. 3B-1, a process of performing boring on the respective hollows 40a having the circular cross-section formed by the first and second grooves 2a and 2b to form hollow channels 40 may be performed. The boring of the hollows 40a may be performed by wire cut electric discharge machining or chemical etching.

The hollows 40a may be enlarged by boring. In this case, at least a part of each of the first weld zones w1 formed around the hollows 40a may be removed during the process of enlarging the hollows 40a by boring. Due thereto, each of the hollow channels 40 may be formed in a form removing at least a part of the first weld zone w1. As such, the hollow channels 40 may be formed inside the joined component 100 by using the hollows 40a of an original shape, or by enlarging the hollows 40a by boring.

As illustrated in FIGS. 3B-1 and 3B-2, each of the hollow channels 40 formed while removing at least a part of the first weld zone w1 may have a form in which no horizontal interface between the parent members 1 exists at an inner surface thereof. This can prevent obstacles such as particles at the horizontal interfaces of the parent members 1 that may be introduced into the hollow channels 40 along the horizontal interfaces.

FIG. 3B-2 is a perspective view illustrating the joined component 100 in which the hollow channels 40 are formed. In this case, the joined component 100 is illustrated in a shape having a quadrangular section. However, the shape of the joined component 100 is not limited thereto.

In the present invention, after the hollow channels 40 are formed as illustrated in FIGS. 3B-1 and 3B-2, inner surfaces of the hollow channels 40 may be anodized or plated. This may be a process for preventing corrosion of the inner surfaces of the hollow channels 40. A process of anodizing or plating the inner surfaces of the hollow channels 40 may be performed in any order as long as the process is performed after the hollow channels 40 are formed.

As illustrated in FIG. 3C, a second friction stir welding may be performed on an upper surface of the joined component 100 in which the hollow channels 40 are formed. The second friction stir welding may be performed in a form of a circular closed curve which closes at least one end of each of the hollow channels 40 formed inside the joined component 100 in which the first and second parent members 1a and 1b are joined. By the second friction stir welding, an outer peripheral region which closes the at least one end of each of the hollow channels 40 may be formed. The outer peripheral region formed by the second friction stir welding may be a second weld zone w2 as one weld zone.

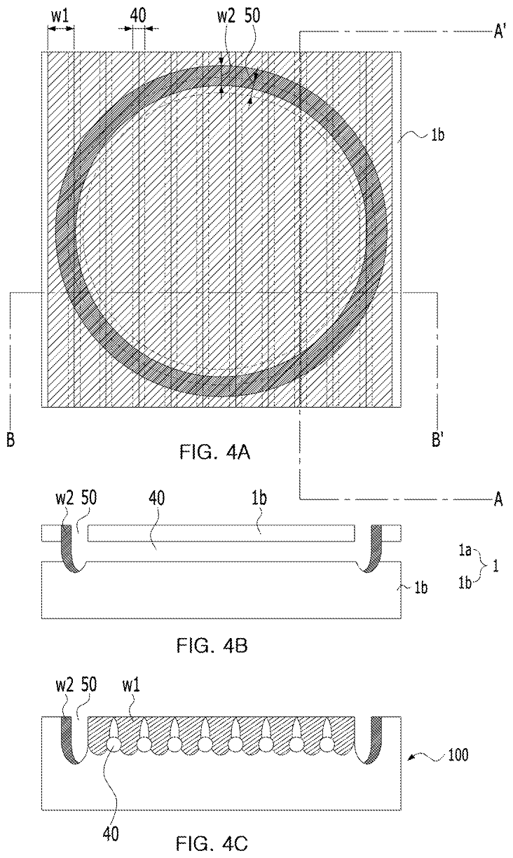

Then, as illustrated in FIG. 4A, a process in which grooving is performed in a region inside the outer peripheral region along the outer peripheral region to form inside the joined component 100 a communication line 50 that is in communication with the hollow channels 40 may be performed. The dotted line indicating the circular closed curve illustrated in FIG. 4A represents the region in which grooving is performed.

As illustrated in FIG. 4A, grooving is performed in the region inside the outer peripheral region along the outer peripheral region formed by the second friction stir welding.

Grooving may be performed to a depth deeper than the depth in which the hollow channels 40 of the joined component 100 are provided, thereby forming inside the joined component 100 the communication line 50 in communication with the hollow channels 40. In the case of the communication line 50, the depth of the communication line 50 is not limited as long as it is possible for the communication line 50 to be in communication with the hollow channels 40 inside the joined component 100.

FIG. 4B is a view illustrating a sectional surface cut along line A-A′ of FIG. 4A. As illustrated in FIG. 4B, grooving is performed in the region inside the outer peripheral region formed by the second friction stir welding to form the communication line 50. The communication line 50 may be formed to be in communication with the hollow channels 40 to allow the hollow channels 40 to be in communication with each other inside the joined component 100 at opposite ends thereof.

An inner surface of the communication line 50 may be anodized or plated. This may be a process for preventing corrosion of the inner surface of the communication line 50. A process of anodizing or plating the inner surface of the communication line 50 may be performed in any order as long as the process is performed after the communication line 50 is formed.

Since the communication line 50 is formed by performing grooving in the region inside the outer peripheral region, a weld zone formed by friction stir welding may exist outside the communication line 50. In detail, at least a part of the second weld zone w2 formed by the second friction stir welding may exist outside the communication line 50.

FIG. 4C is a view illustrating a sectional surface cut along line B-B′ of FIG. 4A. As illustrated in FIG. 4C, an inside of the joined component 100 in which the communication line 50 and the hollow channels 40 are formed may have a form in which a plurality of hollow channels 40 and a plurality of weld zones are formed inside the communication line 50.

The weld zones formed inside the communication line 50 are the first weld zones w1 formed by the first friction stir welding and serve to isolate the fluid holes 20 and the hollow channels 40 inside the joined component 100.

Furthermore, each of the hollow channels 40 may have a form removing at least a part of each of the weld zones, and may have a form in which at least a part of the weld zone is formed around the hollow channel 40.

Since the hollow channel 40 may be formed to remove at least a part of the weld zone, no horizontal interface between the parent members 1 exists at the inner surface thereof. Consequently, when the joined component 100 is used in the semiconductor or display manufacturing process, a temperature control means that is provided in the hollow channel 40 may not be adversely influenced by obstacles introduced along the horizontal interface. This ensures that uniformity of the temperature of the joined component 100 is secured, resulting in minimized deformation of a product, and thus the joined component 100 can function more effectively.

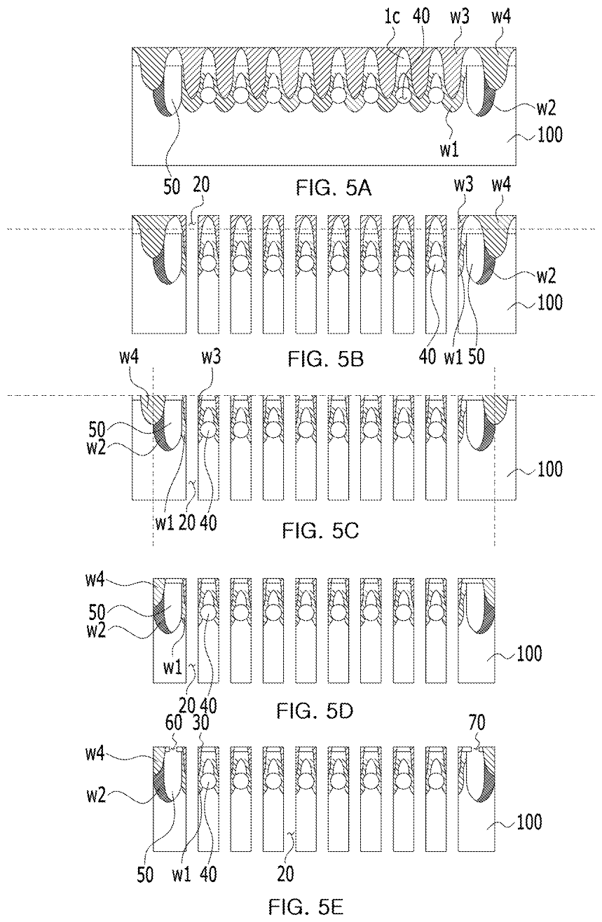

Then, as illustrated in FIG. 5A, a third parent member 1c may be stacked on an upper surface of the joined component 100 in which the hollow channels 40 and the communication line 50 are formed. Referring to FIG. 4B again, the joined component 100 in which the first and second parent members 1a and 1b are joined and the hollow channels 40 and the communication line 50 are formed may have a form in which an opening is formed in an upper surface of the communication line. In other words, the communication line 50 before the third parent member 1c is joined may have a form having an open upper surface.

When the upper surface of the communication line 50 is open, the temperature control means provided in the hollow channels 40 may not be able to properly perform a function thereof. Accordingly, in order to close the open upper surface of the communication line 50, the third parent member 1c may be stacked on the joined component 100 in which the first and second parent members 1a and 1b are joined.

As illustrated in FIG. 5A, the third parent member 1c may be stacked on the joined component 100 in which the communication line 50 and the hollow channels 40 are formed, and then a third friction stir welding may be performed.

The third friction stir welding may be performed along at least a part of a horizontal interface between the joined component 100, in which the first and second parent members 1a and 1b are joined and the hollow channels 40 and the communication line 50 are formed, and the third parent member 1c.

The at least a part of the horizontal interface between the joined component 100, in which the first and second parent members 1a and 1b are joined and the hollow channels 40 and the communication line 50 are formed, and the third parent member 1c is a region where contact junctions are formed, and the third friction stir welding is performed along the contact junctions to form weld zones. The weld zones formed by the third friction stir welding may be third weld zones w3.

The third weld zones w3 may be formed at the contact junctions between the joined component 100, in which the first and second parent members 1a and 1b are joined and the hollow channels 40 and the communication line 50 are formed, and the third parent member 1c at positions corresponding to the first weld zones w1, or may be formed at contact junctions not corresponding to the first weld zones w1.

As illustrated in FIG. 5A, after the third weld zones w3 are formed, and opposite end portions (in FIG. 5A) of the joined component 100 may be welded by the third friction stir welding, or may be welded by a fourth friction stir welding. In the present invention, the opposite end portions (in FIG. 5A) of the joined component 100 are welded by the fourth friction stir welding, and weld zones are formed thereby at the opposite end portions of the joined component 100. The weld zones formed by the fourth friction stir welding may be fourth weld zones w4. Consequently, a joined component 100 in which the first, second, and third parent members 1a, 1b, and 1c are joined from bottom to top is obtained.

Due to the fourth weld zones w4 formed at the opposite end portions (in FIG. 5A) of the joined component 100, among the horizontal interfaces between the joined component 100, in which the hollow channels 40 and the communication line 50 are formed, and the third parent member 1c, horizontal interfaces existing at outer peripheral portions of the joined component 100 may be removed.

In detail, a contact junction may be formed at each horizontal interface between an upper surface of the second weld zone w2 formed outside the communication line 50 and the third parent member 1c. The fourth friction stir welding may be performed along the respective contact junctions to form the fourth weld zones w4, thereby removing the horizontal interfaces existing at the outer peripheral portions of the joined component 100.

This can prevent the problem that when a fluid is provided as a temperature control means, the fluid flowing through the communication line 50 moves along the horizontal interfaces existing at the outer peripheral portions of the joined component 100, or corrodes the horizontal interfaces to cause an adverse action from occurring.

Then, as illustrated in FIG. 5B, a process of planarizing the third weld zones w3 and the fourth weld zones w4 of the joined component 100 may be performed. At least a part of each of the weld zones may be planarized. In this case, at least a part of each of the third and fourth weld zones w3 and w4 existing from the inside of the joined component 100 to the upper surface may be planarized, except for the first and second weld zones w1 and w2 existing inside the joined component 100.

As illustrated in FIG. 5B, planarizing may be performed at a position, indicated by a dotted line, above the contact junctions formed at the horizontal interfaces between the joined component 100, in which the hollow channels 40 and the communication line 50 are formed, and the third parent member 1c.

Then, first fluid holes 20 vertically passing through the parent members 1 and through which a first process fluid passes may be formed in the first and third weld zones w1 and w3.

When the third weld zones 3 are formed at positions that does not correspond to the first weld zones w1, the first fluid holes 20 through which the first process fluid passes may be formed in the first weld zones w1, which are the weld zones formed by the first friction stir welding, to vertically pass through the parent members 1.

In this case, the third weld zones w3 do not correspond to the first weld zones w1 but may be formed around the first weld zones w1 to be adjacent to the first weld zones w1. Accordingly, even when the first fluid holes 20 are formed in the first weld zones w1 to vertically pass through the parent members 1, no horizontal interface may exist at inner surfaces of the first fluid holes 20. This can prevent the problem that the first fluid holes 20 and the hollow channels 40 may communicate with each other along horizontal interfaces and an adverse action may occur due to the horizontal interfaces.

The inner surfaces of the first fluid holes 20 may be anodized or plated. This may be a process for preventing corrosion of the inner surfaces of the first fluid holes 20. A process of anodizing or plating the inner surfaces of the first fluid holes 20 may be performed in any order as long as the process is performed after the first fluid holes 20 are formed.

Then, as illustrated in FIG. 5C, a process of forming an outer periphery of the joined component 100 may be performed. The process of forming the outer periphery of the joined component 100 may be selectively performed. For example, when the joined component 100 is provided in semiconductor manufacturing process equipment or display manufacturing process equipment, the joined component 100 may be provided in a shape having a circular cross-section. In order to form the joined component 100 into a shape having a circular cross-section, the process of forming the outer periphery of the joined component 100 as illustrated in FIG. 5C may be performed.

As illustrated in FIG. 5C, forming of the outer periphery of the joined component 100 may be performed at a position outside the peripheral region existing outside the communication line 50, the position being indicated by a dotted line that is vertical on the plane of FIG. 5C. Since the peripheral region functions to close the communication line 50, it may be preferable that forming of the outer periphery is performed to a position where at least a part of the peripheral region exists outside the communication line 50.

FIG. 5D is a view illustrating the joined component 100 after forming of the outer periphery is performed.

When the temperature control means provided in the hollow channels 40 is the fluid, the joined component 100 may include an injection port 60 through which the fluid is injected into the hollow channels 40, and a discharge port 70 through which the fluid flowing inside the joined component 100 is discharged.

When the temperature control means is a heating wire, the injection port 60 and the discharge port 70 may function as an injection port and a discharge port through which the heating wire is introduced into and withdrawn from the joined component 100.

The injection port 60 and the discharge port 70 may be formed to be in communication with the communication line 50. The communication line 50 is formed to be in communication with the hollow channels 40. Therefore, the injection port 60 and the discharge port 70 may be formed to be in communication with the communication line 50, thereby having a structure in communication with the hollow channels 40.

In the present invention, as one example, the injection port 60 and the discharge port 70 may be formed to vertically pass through the third parent member 1c at one and the other ends (in FIG. 5E) of the third parent member 1c and to be in communication with the communication line 50. As one example, the injection port 60 may be formed at one end (the left side in FIG. 5E) of the third parent member 1c, and the discharge port 70 may be formed at the other end (the right side in FIG. 5E) of the third parent member 1c.

In the present invention, as illustrated in FIG. 5E, although the injection port 60 and the discharge port 70 are illustrated to be formed to vertically pass through the third parent member 1c and to be in communication with the communication line 50, this is only one example. Accordingly, the position where the injection port 60 and the discharge port 70 are formed is not limited thereto.

Furthermore, one end and the other end of the third parent member 1c, where the injection port 60 and the discharge port 70 are formed, are not limited to a specific position. However, the injection port 60 and the discharge port 70 may be formed to vertically pass through the third parent member 1c and to be in communication with the communication line 50 at positions opposite to each other with the hollow channels 40 interposed therebetween.

The injection port 60 and the discharge port 70 may be formed to be in communication with the communication line 50 while passing through the peripheral region outside the communication line 50 at the left and right sides (in FIG. 5E) of the joined component 100. In this case, at least one of the injection port 60 and the discharge port 70 may be formed on at least one side of the left and right sides of the peripheral region of the communication line 50.

Alternatively, the injection port 60 and the discharge port 70 may be formed at positions opposite to the positions where the injection port 60 and the discharge port 70 are formed to be in communication with the communication line 50 while at least partially passing through the joined component 100 from the upper surface (in FIG. 5E) of the joined component 100. In detail, the injection port 60 and the discharge port 70 may be formed to be in communication with the communication line 50 while at least partially passing through the joined component 100 from a lower surface of the joined component 100.

In the present invention, as one example, the temperature control means may be the fluid, and the injection port 60 and the discharge port 70 may be formed in the joined component 100. Alternatively, when the temperature control means is the heating wire, the injection port 60 and the discharge port 70 may function as an injection port and a discharge port for the heating wire.

The joined component 100 formed by the manufacturing method with reference to FIGS. 3A to 5E may be implemented as in the embodiment illustrated in FIGS. 2A and 2B.

The surface of the joined component 100 may be anodized or plated. This may be a process for improving corrosion resistance of the joined component 100. A process of anodizing or plating the surface of the joined component 100 may be performed at the final step in the process of manufacturing the joined component 100.

Anodizing or plating of the surface of the joined component 100 and anodizing or plating of the inner surfaces of the hollow channels 40, the communication line 50, and the first fluid holes 20 described above may be performed individually. Alternatively, in one step after the joined component 100 is manufactured, the inner surfaces of the hollow channels 40, the communication line 50, and the first fluid holes 20 and the surface of the joined component 100 may be all anodized or plated.

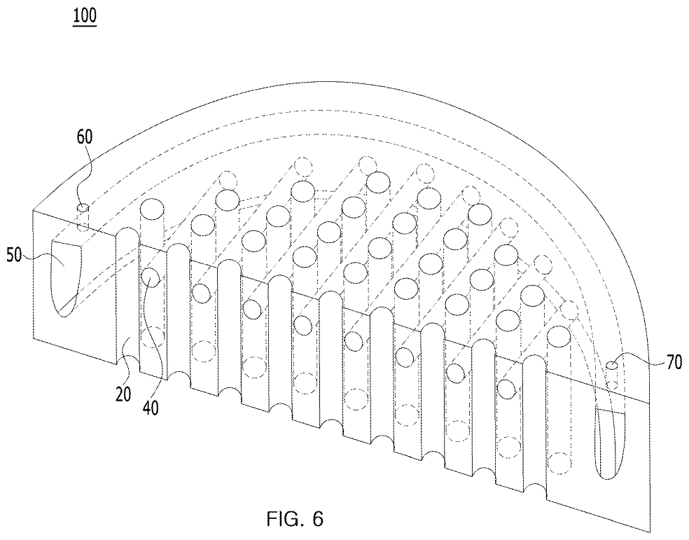

FIG. 6 is a partially sectioned perspective view illustrating the joined component according to the present invention. In FIG. 6, a state in which the weld zones are omitted is illustrated.

As illustrated in FIG. 6, in the joined component 100 according to the present invention, the hollow channels 40 and the fluid holes 20 are formed isolated from each other without being in communication with each other. Furthermore, since no horizontal interface exists between the hollow channels 40 and the fluid holes 20, adverse interaction therebetween can be prevented from occurring along horizontal interfaces.

The formation directions of the hollow channels 40 in which the temperature control means is provided and the formation directions of the fluid holes 20 through which the process fluid passes may be perpendicular to each other inside the joined component 100.

The hollow channels 40 may be formed horizontally inside the joined component 100 with respect to the center line disposed horizontally on the plane of the joined component 100 in FIG. 6 to uniform the temperature inside the joined component 100. The hollow channels 40 may be in communication with each another by the communication line 50.

The hollow channels 40 may have a form branched from the communication line 50 in directions perpendicular to the communication line 50. Due to such a structure, the hollow channels 40 can be uniformly formed inside the joined component 100, and thus the fluid flowing through the hollow channels 40 and the communication line 50 can be uniformly flow throughout the joined component 100. This can ensure uniformity of the temperature of a product and can minimize deformation of the product due to non-uniform temperature distribution.

When the temperature inside the joined component 100 is kept uniform, the joined component 100 can be prevented from deformation of the internal structure. Consequently, the problem of a functional error due to product deformation can be reduced.

The fluid holes 20 may be formed in directions perpendicular to the directions in which the hollow channels 40 are formed. When the joined component 100 is provided in the semiconductor or display manufacturing process equipment, the process fluid passing through the fluid holes 20 may flow from top to bottom in FIG. 6 through the fluid holes 20 formed in the directions perpendicular to the directions in which the hollow channels 40 are formed. The process fluid passing through the fluid holes 20 may be supplied to an upper surface of a part of components constituting a semiconductor or display.

The hollow channels 40 and the fluid holes 20 formed in the directions perpendicular to each other inside the joined component 100 may faithfully perform respective functions thereof due to the structure in which they do not communicate with each other. Furthermore, due to the structure in which no horizontal interface exists inside the joined component 100 by the weld zones, problems such as introduction of particles that move along horizontal interfaces and increased corrosion of the horizontal interfaces can be prevented.

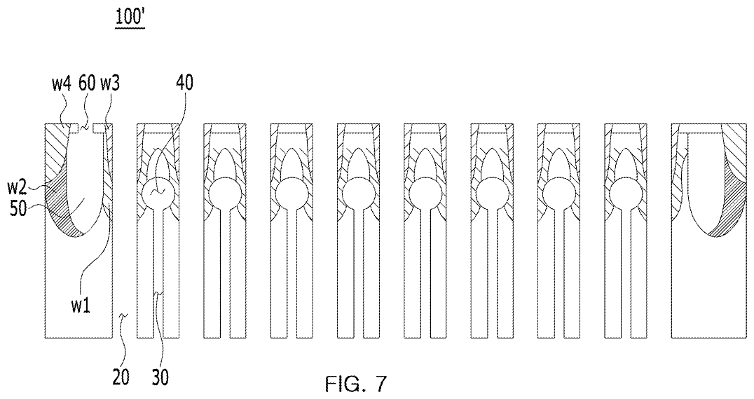

FIG. 7 is a view illustrating a modification of the embodiment of the present invention. The modification differs from the embodiment in provision of a second fluid hole 30 being in communication with a hollow channel 40, passing through a lower portion of a joined component 100′, and through which a second process fluid passes. A description of the same configuration will be replaced with the above description, and a characteristic configuration of the modification will be described in detail as follows.

As illustrated in FIG. 7, the joined component 100′ of the modification includes: a first fluid hole 20 vertically passing through parent members 1 in a weld zone formed by friction stir welding, and through which a first process fluid passes, a second fluid hole 30 being in communication with a hollow channel 40 formed inside the joined component 100′, and through which a second process fluid passes; and a communication line 50 formed inside the joined component 100 to be in communication with the hollow channel 40 and being in communication with an injection port 60 through which the second process fluid is injected into the hollow channel 40.

In the joined component 100′ of the modification, a weld zone formed by friction stir welding between the first fluid hole 20 and the second fluid hole 30 may be formed to remove at a least a part of a horizontal interface between the first fluid hole 20 and the second fluid hole 30. The weld zone formed by friction stir welding between the first and second fluid holes 20 and 30 may be a first weld zone w1 formed by a first friction stir welding. In the joined component 100′, the first process fluid flows into the first fluid hole 20, and the second process fluid flows into the second fluid hole 30, so that different process fluids can be supplied through the first and second fluid holes 20 and 30.

As illustrated in FIG. 7, the second fluid hole 30 is formed to be in communication with the hollow channel 40. As in the modification, when the second fluid hole 30 is formed in the joined component 100′, the hollow channel 40 may be configured to form the second fluid hole 30 through which the second process fluid, different from the first process fluid passing through the first fluid hole 20, passes, rather than performing a function of uniformizing the temperature inside a product.

When the second fluid hole 30 is formed as in the modification, a temperature control means is not provided in the hollow channel 40 being in communication with the second fluid hole 30. However, in addition to the modification, by forming a hollow channel which is not in communication with the second fluid hole 30 and in which the temperature control means is provided, it is possible to secure uniformity of the product temperature.

When the hollow channel, which is not in communication with the second fluid hole 30 and in which the temperature control means is provided, is formed in the joined component 100′ of the modification, the structure of the joined component 100′ is not limited as long as a structure in which the hollow channel in which the temperature control means is provided is not in communication with the first and second fluid holes 20 and 30, and no horizontal interface exists between the first and second fluid holes 20 and 30 and the hollow channel in which the temperature control means is provided.

The second fluid hole 30 is formed to be in communication with the hollow channel 40 and to pass through the lower portion of the joined component 100′. Due thereto, the second process fluid introduced into the hollow channel 40 through the communication line 50 may be introduced into the second fluid hole 30 and supplied externally.

In the joined component 100′ of the modification, inner surfaces of the first and second fluid holes 20 and 30 and the communication line 50 and the surface of the joined component 100′ may be anodized or plated. In this case, respective configurations may be individually anodized or plated, and may be anodized or plated in one step after the joined component 100′ is manufactured. Due to anodizing or plating, the joined component 100′ can have an effect of improving corrosion resistance.

The joined component 100′ of the modification may have a structure in which the first fluid hole 20 and the second fluid hole 30 are not in communication with each other by the weld zone. This makes it possible to spray different process fluids from the respective fluid holes.

Conventionally, a fluid passing member having a structure for spraying a process fluid is configured such that process fluids are injected thereinto in an already mixed state and the mixed process fluids are sprayed through fluid holes. However, when the process fluids are injected into the fluid passing member in a mixed state, the process fluids may react in the fluid passing member before being sprayed through the fluid holes, causing undesired chemical reaction to occur. This may cause a problem that the process fluids are not properly sprayed to a process fluid spray object, resulting in production of a defective product.

Furthermore, when manufacturing a joined component having a structure in which the first and second fluid holes 20 and 30 are formed by welding or brazing as the technology underlying the present invention illustrated in FIGS. 1A and 1B, there may arise a problem that the weld joints or braze joints 3 may be corroded by the first and second process fluids. This corrosion may cause particles to be generated inside the first and second fluid holes 20 and 30, and the particles may be entrained in the first and second process fluids and sprayed theretogether, thereby resulting in production of a defective product.

However, the present invention provides a structure in which the first and second fluid holes 20 and 30 are not in communication with each other so that the first process fluid and the second process fluids are separately injected into the joined component 100′ and do not mix with each other inside the joined component 100′. This can prevent the problem of undesired chemical reaction occurring inside the joined component 100′ before the process fluids are sprayed therefrom.

Furthermore, the first and second fluid holes 20 and 30 are configured such that no horizontal interface exists between the first and second fluid holes 20 and 30 by the weld zone formed therebetween. This can prevent the problem that the first process fluid and the second process fluid move along the horizontal interface and mix with each other. In other words, mutual physical and chemical action between the first and second fluid holes 20 and 30 is prevented by the weld zone.

As described above, the joined component 100′ of the modification may have a structure in which the first and second fluid holes 20 and 30 are isolated from each other inside the joined component 100′. This makes it possible to spray different process fluids from the respective fluid holes. Consequently, when the joined component 100′ is provided in semiconductor or display manufacturing process equipment, it is possible to perform a thin film forming process more effectively.

A method of manufacturing the joined component 100′ of the modification may further include forming a second fluid hole 30 being in communication with a hollow channel 40, passing through a lower portion of the joined component 100′, and through which a second process fluid passes, in addition to the method of manufacturing the joined component 100 of the embodiment with reference to FIGS. 3A to 5E. In this case, the forming the second fluid hole 30 may be performed in any order as long as being performed after a process of welding a third parent member 1c by a third friction stir welding as illustrated in FIG. 5A.

However, the joined component 100′ of the modification may include an injection port 60 through which the second process fluid is injected into the second fluid hole 30. The injection port 60 may be formed to be in communication with a communication line 50 and may be formed to pass through the third parent member 1c or a peripheral region.

In the joined component 100′ of the modification with reference to FIG. 7, as one example, the left side in FIG. 7 represents one end of the third parent member 1c, and the injection port 60 is formed to be in communication with the communication line 50 while vertically passing through the third parent member 1c.

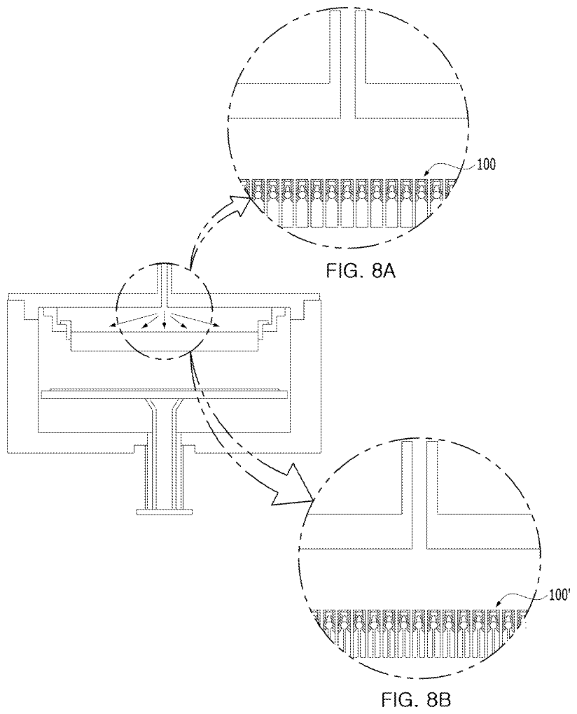

The joined components 100 and 100′ according to the embodiment and the modification of the present invention may be provided in semiconductor manufacturing process equipment or display manufacturing process equipment. FIGS. 8A and 8B are views schematically illustrating the semiconductor or display manufacturing process equipment including the joined components according to the embodiment and the modification of the present invention.

The semiconductor manufacturing process equipment or display manufacturing process equipment includes etching equipment, cleaning equipment, heat treatment equipment, ion implantation equipment, sputtering equipment, CVD equipment, or the like which will be described below. Therefore, the joined components 100 and 100′ according to the present invention may be joined components provided in etching equipment, cleaning equipment, heat treatment equipment, ion implantation equipment, sputtering equipment, or CVD equipment.

FIG. 8A is an enlarged view illustrating a part of the joined component 100 according to the embodiment provided in the semiconductor manufacturing process equipment or display manufacturing process equipment, and FIG. 8B is an enlarged view illustrating a part of the joined component 100′ according to the modification provided in the semiconductor manufacturing process equipment or display manufacturing process equipment.

First, the semiconductor manufacturing process equipment or display manufacturing process equipment including the joined component 100 according to the embodiment will be described with reference to FIG. 8A.

The semiconductor manufacturing process equipment or display manufacturing process equipment including the joined component 100 may be etching equipment. The joined component 100 may be a joined component 100 for supplying a process fluid for an etching process to a workpiece. The process fluid passes through the fluid holes 20. The etching equipment may be used to pattern a portion on a wafer or glass using the process fluid passing through the fluid holes 20 of the joined component 100. The etching equipment may be wet etching equipment, dry etching equipment, plasma etching equipment, or reactive ion etching (RIE) equipment.

When the joined component 100 of the embodiment is provided in the etching equipment, uniformity of the product temperature can be secured by the temperature control means provided in the hollow channels 40. Consequently, it is possible to minimize deformation of a product. Furthermore, the horizontal interfaces between the hollow channels 40 and the fluid holes 20 are removed by the weld zones formed between the hollow channels 40 and the fluid holes 20, and thus no horizontal interface exists between the hollow channels 40 and the fluid holes 20. Due to the structure in which no horizontal interface exists between the hollow channels 40 and the fluid holes 20, the joined component 100 can be prevented from undergoing the problems of increased corrosion at the horizontal interfaces and particle introduction due to the horizontal interfaces. Consequently, it is possible to reduce the rate of defects due to spraying of process fluids in which particles are entrained, and to reduce the occurrence of obstacles that may cause functional errors to occur inside a product.

The semiconductor manufacturing process equipment of display manufacturing process equipment including the joined component 100 may be cleaning equipment. The joined component 100 may be a joined component 100 for supplying a process fluid for a cleaning process to a workpiece. The process fluid passes through the fluid holes 20. The cleaning equipment may be used to clean particulate or chemical foreign substances that may cause defects in a manufacturing process, using the process fluid passing through the fluid holes 20 of the joined component 100. The cleaning equipment may be a cleaner or a wafer scrubber.

When the joined component 100 of the embodiment is provided in the cleaning equipment, uniformity of the product temperature can be secured by the temperature control means provided in the hollow channels 40, and product deformation can be minimized. Furthermore, due to the weld zones formed between the hollow channels 40 and the fluid holes 20, a structure in which no horizontal interface exists between the hollow channels 40 and the fluid holes 20 and no horizontal interface exists at the inner surfaces of the hollow channels 40 and the fluid holes 20 is formed. This makes it possible to prevent the problem of increased corrosion, and particle generation at the horizontal interfaces.

The semiconductor manufacturing process equipment or display manufacturing process equipment including the joined component 100 may be heat treatment equipment. The joined component 100 may supply a process fluid for a heat treatment process to a workpiece. The process fluid may be supplied through the fluid holes 20. The heat treatment equipment including the joined component 100 may apply heat at a high speed to activate dopants implanted by a method such as ion implantation and may form an oxide film, a nitride film, and the like.

When the joined component 100 is provided in the heat treatment equipment, uniformity of the product temperature can be secured by the temperature control means provided in the hollow channels 40 in which no horizontal interface exists at the inner surfaces thereof by the weld zones formed by welding the first and second parent members 1a and 1b by friction stir welding. Consequently, it is possible to minimize deformation of a product.

Due to the structure in which no horizontal interface exists at the inner surfaces of the hollow channels 40, increased corrosion at the horizontal interfaces can be prevented. Furthermore, obstacles such as particles introduced along the horizontal interfaces from interfering with function can be prevented. In the joined component 100 according to the present invention, no horizontal interface exists between the hollow channels 40 and the fluid holes 20 by the weld zones. Due thereto, adverse interaction which may occur between the hollow channels 30 and the fluid holes 20 due to the horizontal interfaces can be prevented. Consequently, obstacles interfering with effective process fluid spraying can be eliminated, and thus the joined component 100 can faithfully perform functions thereof and the rate of defects of a wafer or glass can be reduced.

The semiconductor manufacturing process equipment or display manufacturing process equipment including the joined component 100 may be ion implantation equipment. The joined component 100 may be a joined component 100 for supplying a process fluid for an ion implantation process to a workpiece. The process fluid passes through the fluid holes 20 formed in the first weld zones w1 and in which no horizontal interface exists at the inner surfaces thereof. The ion implantation equipment including the joined component 100 may consciously pressurize impurity atoms (preferably 3 to 5) to give a certain electrical resistance onto the surface of a wafer or glass.

When the joined component 100 of the embodiment is provided in the ion implantation equipment, uniformity of the product temperature can be secured by the temperature control means provided in the hollow channels 40. Consequently, it is possible to minimize deformation of a product. Furthermore, due to the structure in which due to the weld zones formed between the hollow channels 40 and the fluid holes 20, no horizontal interface exists between the hollow channels 40 and the fluid holes 20 and no horizontal interface exists at the inner surfaces of the hollow channels 40 and the fluid holes 20, thus the problems of increased corrosion at the horizontal interfaces and particle introduction due to the horizontal interfaces can be prevented. Consequently, it is possible to reduce the rate of defects due to spraying of process fluids in which particles are entrained, and to reduce the occurrence of obstacles that may cause functional errors to occur inside a product.

The semiconductor manufacturing process equipment or display manufacturing process equipment including the joined component 100 may be sputtering equipment. The joined component 100 may supply a process fluid for a sputtering process to a workpiece, and the process fluid may pass through the fluid holes 20 in which no horizontal interface exists at the inner surfaces thereof. The sputtering equipment including the joined component 100 may form a metal film on the surface of a wafer or glass using a sputter profile.

When the joined component 100 of the embodiment is provided in the sputtering equipment, uniformity of the product temperature can be secured by the temperature control means provided in the hollow channels 40. Consequently, it is possible to minimize deformation of a product. Furthermore, due to the weld zones formed between the hollow channels 40 and the fluid holes 20, a structure in which no horizontal interface exists between the hollow channels 40 and the fluid holes 20 and no horizontal interface exists at the inner surfaces of the hollow channels 40 and the fluid holes 20 is formed. This makes it possible to prevent the problem of increased corrosion, and particle generation at the horizontal interfaces.

The semiconductor manufacturing process equipment or display manufacturing process equipment including the joined component 100 may be CVD equipment. The joined component 100 may supply a process fluid for a CVD process to a workpiece through the fluid holes 20 in which no horizontal interface exists at the inner surfaces thereof. The CVD equipment including the joined component 100 may be used to deposit a thin film on the surface of a wafer or glass by chemical reaction occurring in electrons or vapor phases by exciting a reaction process fluid composed of elements with energy, such as a thermal plasma discharge, photo-discharge, or the like. The CVD equipment may be atmospheric pressure CVD equipment, reduced pressure CVD equipment, plasma CVD equipment, photo-initiated CVD equipment, or MO-CVD equipment.

The joined component 100 provided in the CVD equipment as the semiconductor manufacturing process equipment may be a showerhead, and the joined component 100 provided in the CVD equipment as the display manufacturing process equipment may be a diffuser.

The joined component 100 provided in the CVD equipment may supply the process fluid through the fluid holes 20 in which no horizontal interface exists at the inner surfaces thereof by the weld zones. Since the fluid holes 20 having such a structure is prevented from undergoing increased corrosion, and particle generation at the horizontal interfaces, the efficiency of spraying the process fluid by the joined component 100 can be increased.

Furthermore, each of the hollow channels 40 of the joined component 100 is formed to remove at least a part of each of the weld zones formed by welding the first and second parent members 1a and 1b by friction stir welding, and thus no horizontal interface exists at the inner surfaces thereof. This can prevent obstacles which may occur in the temperature control means due to the horizontal interfaces.

The joined component 100 according to the present invention may have a structure in which no horizontal interface exists between the hollow channels 40 and the fluid holes 20 by the weld zones formed between the hollow channels 40 and the fluid holes 20. This is a structure that can prevent adverse interaction due to the horizontal interfaces, and it is possible to reduce obstacles that interfere with a function of the joined component 100, thereby enabling for the joined component 100 to perform the function more effectively.

As illustrated in FIG. 8B, the semiconductor manufacturing process equipment or display manufacturing process equipment may include the joined component 100′ of the modification.

In this case, the joined component 100′ of the modification may be provided in semiconductor manufacturing process equipment or display manufacturing process equipment including etching equipment, cleaning equipment, heat treatment equipment, ion implantation equipment, sputtering equipment, or CVD equipment, and may spray different fluids through the first and second fluid holes 20 and 30 separately.

The joined component 100′ of the modification may be provided in the semiconductor manufacturing process equipment or display manufacturing process equipment to perform a process associated with each equipment using the first process fluid passing through the first fluid holes 20 and the second process fluid passing through the second fluid holes 30.

The joined component 100′ of the modification differs from the joined component 100 of the embodiment in that the joined component 100′ is provided in etching equipment, cleaning equipment, heat treatment equipment, ion implantation equipment, sputtering equipment, or CVD equipment to spray the first process fluid and the second process fluid separately.

Since the joined component 100′ of the modification is provided in the semiconductor manufacturing process equipment or display manufacturing process equipment to supply the first and second process fluids separately, it is possible to prevent the problem that in the related art, the process fluids are injected into the fluid passing member in a mixed state and may react in the fluid passing member before being sprayed, causing undesired chemical reaction to occur.

Furthermore, no horizontal interface exists between the first and second fluid holes 20 and 30 by the weld zones formed between the first and second fluid holes 20 and 30. Due thereto, adverse interaction which may occur between the first and second fluid holes 20 and 30 due to the horizontal interfaces can be prevented, thereby increasing the functional efficiency of the joined component 100′.

As described above, the joined components 100 and 100′ according to the embodiment and the modification of the present invention may be formed in a structure in which flow paths (e.g., the fluid holes 20 and the hollow channels 40 in the case of the joined component 100 of the embodiment, and the first and second fluid holes 20 and 30 in the case of the joined component 100′ of the modification) provided in the joined components are not in communication with each other by the weld zones. Furthermore, a structure in which no horizontal interface exists by the weld zones formed between the respective flow paths may be formed, and thus adverse interaction that may occur between the paths due to the horizontal interfaces can be prevented.

Furthermore, each of the flow paths is formed to remove at least a part of each of the weld zones and thus no horizontal interface exists at the inner surface thereof, thereby making it possible to prevent the problem of increased corrosion, and particle generation, which may occur due to existence of the horizontal interface at the inner surface. Consequently, it is possible to reduce the rate of defective products that may occur due to spraying of process fluids in which particles are entrained.

Although exemplary embodiments of the present invention have been described for illustrative purposes, those skilled in the art will appreciate that various modifications, additions and substitutions are possible, without departing from the scope and spirit of the invention as disclosed in the accompanying claims.

What is claimed is:

1. A joined component formed by welding at least two parent members by friction stir welding, the joined component comprising:
a hollow channel formed inside the joined component and in which a temperature control means is provided;
a communication line formed inside the joined component and being in communication with the hollow channel; and
a fluid hole vertically passing through the parent members in a weld zone formed by friction stir welding, and through which a process fluid passes,
wherein the weld zone formed by friction stir welding that is formed between the hollow channel and the fluid hole removes at least a part of a horizontal interface between the hollow channel and the fluid hole.

2. The joined component of claim 1, wherein the temperature control means is a fluid or a heating wire.

3. The joined component of claim 1, wherein opposite ends of the hollow channel are in communication with the communication line.

4. The joined component of claim 1, wherein the communication line is formed peripherally outside the hollow channel while forming a closed curve.

5. The joined component of claim 1, wherein the fluid hole is formed between neighboring hollow channels.

6. The joined component of claim 1, wherein a weld zone formed by friction stir welding is formed outside the communication line.

7. The joined component of claim 1, wherein a direction in which the hollow channel is formed and a direction in which the fluid hole is formed are perpendicular to each other.

8. The joined component of claim 1, wherein an inner surface of each of the hollow channel, the communication line, and the fluid hole, and a surface of the joined component are anodized or plated.

9. A joined component formed by welding at least two parent members by friction stir welding, the joined component comprising:
a first fluid hole vertically passing through the parent members in a weld zone formed by friction stir welding, and through which a first process fluid passes;
a second fluid hole being in communication with a hollow channel formed inside the joined component, and through which a second process fluid passes; and
a communication line formed inside the joined component to be in communication with the hollow channel, and being in communication with an injection port through which the second process fluid is injected into the hollow channel,
wherein the weld zone formed by friction stir welding that is formed between the first and second fluid holes removes at least a part of a horizontal interface between the first and second fluid holes, and
the first process fluid is introduced into the first fluid hole and the second process fluid is introduced into the second fluid hole, such that the first and second fluid holes respectively supply different process fluids separately.

10. The joined component of claim 9, wherein an inner surface of each of the first fluid hole, the second fluid hole, and the communication line, and a surface of the joined component are anodized or plated.

11. The joined component of claim 9, wherein the joined component is a joined component provided in etching equipment, cleaning equipment, heat treatment equipment, ion implantation equipment, sputtering equipment, or CVD equipment, and through which a process fluid for a semiconductor manufacturing process or display manufacturing process passes.

12. A method of manufacturing a joined component, the method comprising:
welding at least two parent members each of which includes at least one groove by a first friction stir welding, thereby forming a joined component such that a hollow channel is formed in the joined component by the groove;
welding an upper surface of the joined component by a second friction stir welding to close at least one end of the hollow channel and form an outer peripheral region, and performing grooving in a region inside the outer peripheral region along the outer peripheral region, thereby forming a communication line; and
forming a first fluid hole vertically passing through the parent members in a weld zone formed by the first friction stir welding, and through which a first process fluid passes.

13. The method of claim 12, further comprising:
forming a second fluid hole being in communication with the hollow channel, and through which a second process fluid passing through a lower portion of the joined component passes.
